(19) United States
(12) Patent Application Publication
(10) Pub. No.: US 2009/0250008 A1
(43) Pub. Date: Oct. 8, 2009

(54) GAS TREATMENT APPARATUS

(75) Inventors: Noriaki Matsushima, Yamanashi (JP); Tsuyoshi Takahashi, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/996,077

(22) PCT Filed: Jul. 18, 2006
(86) PCT No.: PCT/JP2006/314147

§ 371 Date: Jan. 18, 2008

(30) Foreign Application Priority Data
Jul. 19, 2005 (JP) 2005-208760

(51) Int. Cl. C23C 16/54

(52) U.S. Cl. 118/728

(57) ABSTRACT

A film forming apparatus includes a chamber for accommodating a wafer; a mounting table arranged in the chamber to mount the wafer thereon; a shower head arranged to face the mounting table for injecting a processing gas into the chamber; and a gas exhaust mechanism for evacuating the chamber. The shower head is provided with a center portion in which a plurality of gas injection holes are formed for injecting the processing gas; and an outer peripheral portion disposed at outside of the center portion without having the gas injection holes. The film forming apparatus further includes a heat dissipating mechanism for dissipating heat of the shower head from the entire circumference of the outer peripheral portion to the atmosphere.

### FIELD OF THE INVENTION

The present invention relates to processing apparatus for performing a processing of a target substrate by using a processing gas.

### BACKGROUND OF THE INVENTION

To meet a recent trend of high integration and speed-up of a large-scale integration (LSI) circuit, a design rule for a semiconductor device constituting the LSI is getting finer. Accordingly, a gate insulating film of a complimentary metal oxide semiconductor (CMOS) device is required to have an equivalent Sio₂ film thickness (EOT: equivalent oxide thickness) smaller than or equal to about 1.5 nm. Materials having a high dielectric constant that are also known as “high-k materials” are attracting attention as materials capable of realizing a thin insulating film without increasing a gate leak current.

To be used for the gate insulating film, a high-k dielectric material is required not to undergo inter-diffusion with a silicon substrate and also needs to be stable thermodynamically. From such a point of view, oxides of hafnium, zirconium and lanthanide elements or metal silicates thereof are deemed to be promising.

Recently, CMOS logic devices of metal silicate films such as a hafnium silicate (HfSiOₓ) film or a zirconium silicate (ZrSiOₓ) film have been extensively evaluated, and are expected as highly promising candidates for a next-generation gate insulating film thanks to their high carrier mobility.

As a method for forming a thin-thickness insulating film of the high-k dielectric material with a high precision, there is known a metal organic chemical vapor deposition (MOCVD) technique for forming a thin film by using a thermal decomposition of a gasified organic metal compound.

Generally, in a CVD method including the MOCVD technique, a source gas is supplied to a heated semiconductor wafer W on a mounting table from a shower head disposed to face the mounting table, and a thin film is formed on the semiconductor wafer by a thermal decomposition or a reduction reaction of the source gas. Typically, to supply the gas uniformly, a flat gas diffusion space having a size identical with a diameter of the semiconductor wafer is provided inside the shower head, and a number of gas injection holes communicating with the gas diffusion space are provided in a surface of the shower head which faces the semiconductor wafer in a uniform manner (see, for example, Japanese Patent Laid-open Publication No. H8-291385).

However, if the flat gas diffusion space is present inside the shower head, the space impedes a heat transfer (heat radiation) toward the rear side of the shower head. As a result, the shower head is heated up by radiant heat from the mounting table which heats the wafer W, so that the temperature of the shower head increases while the film formation is repeated.

Particularly, with regard to the MOCVD method which uses the thermal decomposition of the source gas, an undesirable thermal decomposition reaction would take place inside the shower head or in a pipe upstream of the shower head if the temperature of the shower head increase over a thermal decomposition temperature of the source gas, resulting in a decrease in the concentration of the source gas supplied to the semiconductor wafer or a decrease in the reflectivity of the shower head due to an attachment of decomposed products of the source gas to the shower head. In such cases, the temperature of the semiconductor wafer would be reduced, resulting in poor film formation.

Moreover, if the temperature of the shower head increases with a lapse of time as described above, it would cause a great deviation in film quality or composition. Besides, if the decomposed products are separated from the surface of the shower head and stick to the semiconductor wafer as foreign substances, poor film formation would be resulted.

### SUMMARY OF THE INVENTION

In view of the foregoing, the present invention provides a processing apparatus capable of suppressing a temperature rise of a gas injection mechanism such as a shower head and capable of reducing defects or nonuniformity of processing due to the temperature rise of the gas injection mechanism.

In accordance with a first aspect of the present invention, there is provided a processing apparatus including: a processing vessel for accommodating a target substrate to be processed; a mounting table disposed in the processing vessel, for mounting the target substrate thereon; a gas injection mechanism disposed to face the mounting table, for injecting a processing gas into the processing vessel; a gas exhaust mechanism for evacuating the processing vessel; and a heat dissipating mechanism for dissipating a heat of the gas injection mechanism toward the atmosphere, wherein the gas injection mechanism includes: a center portion provided with a number of gas injection holes for injecting the processing gas; an outer peripheral portion provided at outside of the center portion where no gas injection hole is present, and the heat dissipation member dissipates the heat of the gas injection mechanism toward the atmosphere from the substantially entire circumference of the outer peripheral portion.

In accordance with a second aspect of the present invention, there is provided a processing apparatus including: a processing vessel for accommodating a target substrate to be processed; a mounting table disposed in the processing vessel, for mounting the target substrate thereon; a gas injection mechanism disposed to face the mounting table, for injecting a processing gas into the processing vessel; a gas exhaust mechanism for evacuating the processing vessel; and a heat dissipating mechanism for dissipating a heat of the gas injection mechanism toward the atmosphere, wherein the gas injection mechanism includes: a gas introduction part provided with an gas inlet hole for introducing the processing gas; a gas injection part provided with a number of gas injection holes for injecting the processing gas toward the mounting table; and a gas diffusion part disposed between the gas introduction part and the gas injection part, for diffusing the processing gas, wherein the gas injection part includes: a center portion provided with the gas injection holes for injecting the processing gas; and an outer peripheral portion provided at outside of the center portion where no gas injection hole is present, wherein the heat dissipation member dissipates the heat of the gas injection mechanism toward the atmosphere from the substantially entire circumference of the outer peripheral portion.

In the first and second aspects of the present invention, the heat dissipating mechanism may include a heat dissipation member annularly disposed along the substantially entire circumference of the outer peripheral portion and being in contact with the atmosphere, and the heat dissipation member transfers and dissipates the heat of the gas injection mechanism toward the atmosphere. In this case, the heat dissipation member may further include an annular heat transfer control member for controlling a heat transfer between the outer peripheral portion and the heat dissipation member, and the heat dissipation member may be provided to contact the outer peripheral portion along the substantially entire circumference thereof via the heat transfer control member. Further, the heat dissipating mechanism may include a cooling mechanism provided in the heat dissipation member, for cooling the gas injection mechanism from the outer peripheral portion thereof, wherein the cooling mechanism may include an annular coolant path or a thermally conductive semiconductor element through which a cooling medium flows. Moreover, the heat dissipating mechanism may further include a heating mechanism for controlling a temperature of the gas injection mechanism by heating it.

In accordance with a third aspect of the present invention, there is provided a processing apparatus including: a processing vessel for accommodating a target substrate to be processed; a mounting table disposed in the processing vessel, for mounting the target substrate thereon; a gas injection mechanism disposed to face the mounting table, for injection a processing gas into the processing vessel; and a gas exhaust mechanism for evacuating the processing vessel, wherein the gas injection mechanism includes: a gas introduction part provided with an gas inlet hole for introducing the processing gas; a gas injection part provided with a number of gas injection holes for injecting the processing gas toward the mounting table; and a gas diffusion part disposed between the gas inlet unit and the gas injection part, for diffusing the processing gas, wherein the gas injection part includes: a center portion provided with the gas injection holes for injecting the processing gas; and an outer peripheral portion provided at outside of the center portion where no gas injection hole is present, the outer peripheral portion being annularly formed and having a heat dissipation surface on a top side thereof along the substantially entire circumference thereof, wherein the processing apparatus further includes: a heat dissipation member annularly disposed along the substantially entire circumference of the outer peripheral portion and being in contact with the atmosphere, and the heat dissipation member transfers and dissipates the heat of the gas injection mechanism toward the atmosphere; a heat transfer control member disposed between the heat dissipation surface and the heat dissipation member to contact the heat dissipation surface and the heat dissipation member along the substantially entire circumference thereof, for controlling a heat transfer from the outer peripheral portion to the heat dissipation member by controlling a contact area between the heat dissipation surface and the heat dissipation member; a cooling mechanism disposed in the heat dissipation member, for cooling the gas injection mechanism; and a heating mechanism disposed in the heat dissipation member, for controlling a temperature of the gas injection mechanism by heating the heat dissipation member.

In the third aspect of the present invention, the cooling mechanism may include an annular coolant path through which a cooling mechanism flows. Further, the cooling mechanism may include a thermally conductive semiconductor element.

In any one of the first to third aspects of the present invention, a covering member provided with the gas injection holes may be detachably disposed at a surface of the center portion that faces the mounting table. In this case, it is preferable that the surface of the covering member is alumite-treated.

The processing apparatus may perform a metal oxide chemical vapor deposition. Further, the processing gas may contain a hafnium-based source material.

In accordance with the present invention, heat of the gas injection part is efficiently dissipated toward the atmosphere outside the processing vessel from the substantially entire circumference of the outer peripheral portion via the heat dissipating mechanism (or the heat dissipation member) . Accordingly, a temperature rise of the gas injection mechanism is effectively suppressed.

As a result, in a case of a film forming process that uses a thermal decomposition reaction of a processing gas supplied toward a target substrate on the mounting table from the gas injection mechanism, the gas injection mechanism can be maintained at a temperature level less than a decomposition temperature of the source gas. Accordingly, it is possible to prevent an undesirable thermal decomposition of the source gas in the gas injection mechanism or in a pipe connected thereto due to overheating of the gas injection mechanism before the source gas reaches the target substrate. Further, it is possible to suppress decrease in a film forming rate (increase in the processing time) and variation in the film thickness and quality due to decrease or deviation in the concentration of the source gas or the variation in the reflectivity of the gas injection mechanism by attachments of decomposed products thereto. Furthermore, it is possible to suppress occurrence of defective film due to attachments of the decomposed products to the target substrate after being peeled off from the gas introduction mechanism.

### BRIEF DESCRIPTION OF THE DRAWINGS

FIG. 1 is a cross sectional view of a film forming apparatus as an example of a processing apparatus in accordance with an embodiment of the present invention;

FIG. 2 sets forth a cross sectional view showing major parts of a chamber and a shower head of the film forming apparatus;

FIG. 3 presents a cutaway perspective view showing major parts of the chamber and the shower head;

FIG. 4 illustrates a modification of a heat dissipation member that constitutes the film forming apparatus;

FIG. 5 depicts a graph showing a temperature of the shower head and thickness of a hafnium silicate film when a film forming process is performed on a plurality of wafers successively by using the film forming apparatus;

FIG. 6 provides a graph showing a correlation between a wafer temperature and a mounting table temperature in cases where a film forming gas is supplied into the chamber to form a film having a thickness of 1.5 μm and a film having a thickness of 6 μm, respectively; and

FIG. 7 offers a graph showing a correlation between a shower head temperature and a mounting table temperature in cases where a film forming gas is supplied into the chamber to form a film having a thickness of 1.5 μm and a film having a thickness of 6 μm, respectively.

### DETAILED DESCRIPTION OF THE EMBODIMENT

Hereinafter, an embodiment of the present invention will be described in detail with reference to the accompanying drawings.

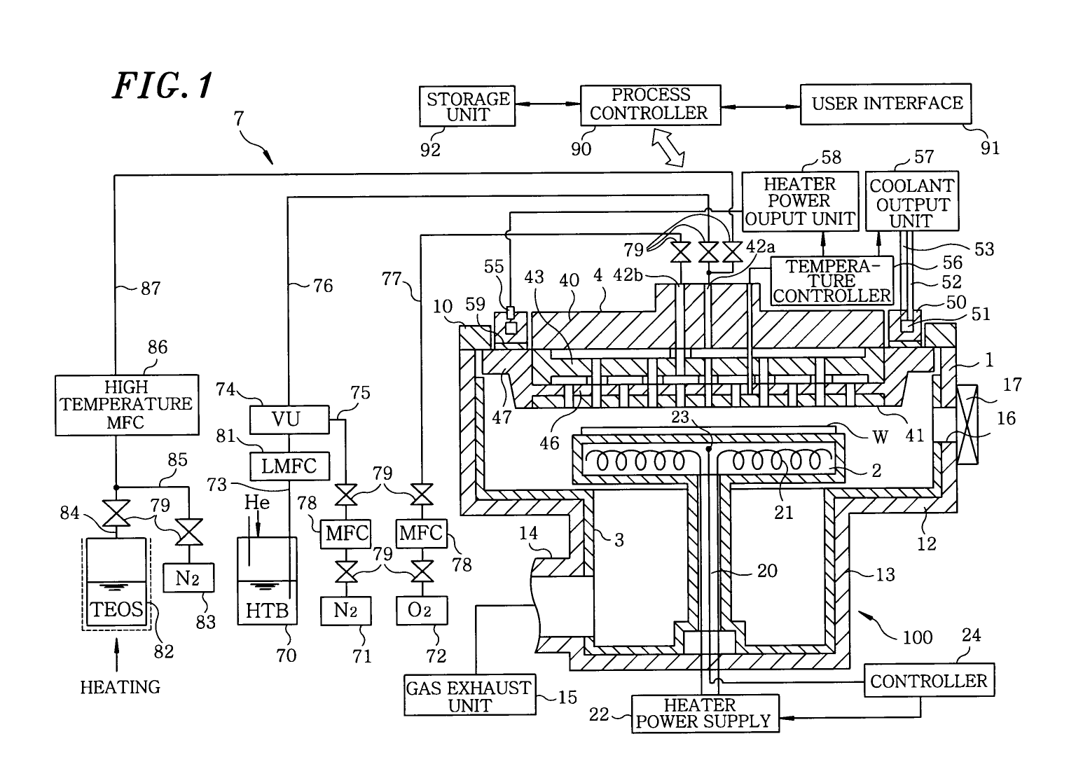

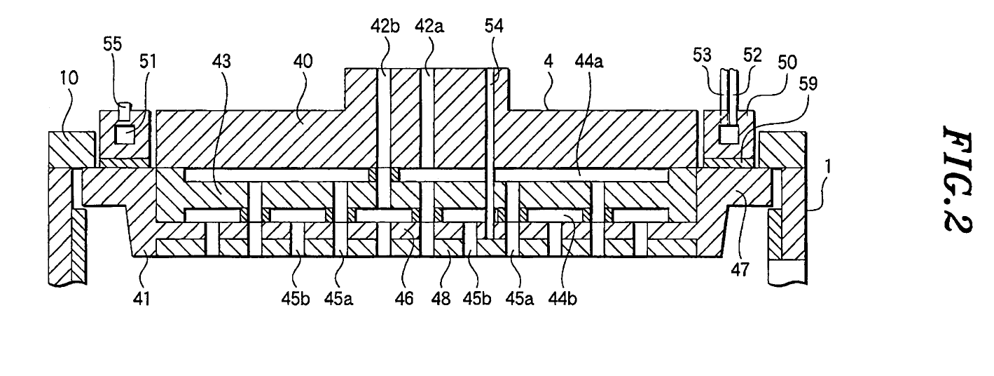

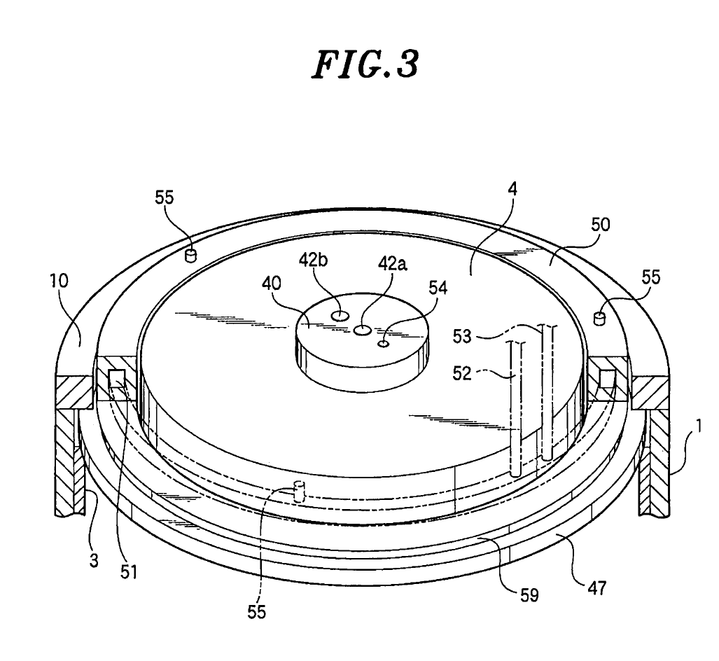

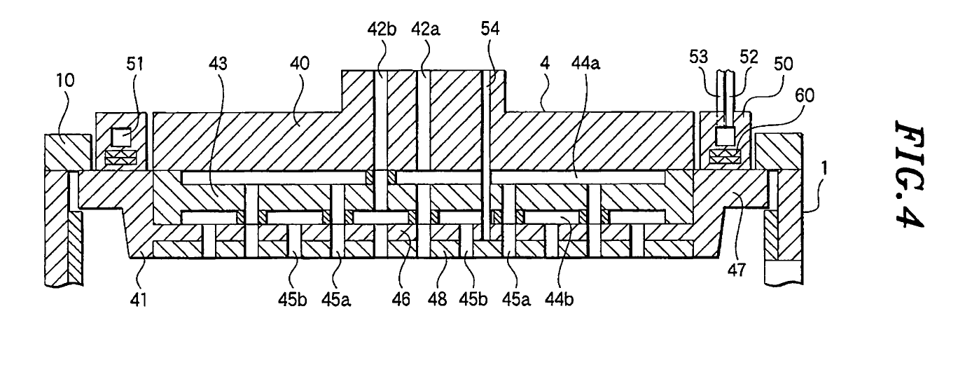

FIG. 1 is a cross sectional view showing a film forming apparatus as an example of a processing apparatus in accordance with an embodiment of the present invention. FIG. 2 sets forth a cross sectional view showing major parts of a chamber and a shower head of the film forming apparatus, and FIG. 3 depicts a cutaway perspective view of the chamber and the shower head.

The film forming apparatus 100 includes a substantially cylindrical chamber 1 which is configured as an airtight processing vessel. Inside the chamber 1, a mounting table 2 for mounting thereon a Si substrate (wafer) W to be processed is sustained on a cylindrical supporting member 20 disposed at a central bottom portion of the chamber 1. The mounting table 2 is made of ceramic such as AlN. Further, a heater 21 is embedded in the mounting table 2, and a heater power supply 22 is connected to the heater 21. Meanwhile, a thermocouple 23 is provided near the top surface of the mounting table 2, and a signal from the thermocouple 23 is transmitted to a controller 24. The controller 24 sends a command to the heater power supply 22 depending on the signal from the thermocouple 23 and controls the heating operation of the heater 21, thereby regulating the temperature of the wafer W at a specific temperature level.

A quartz liner 3 is provided on the inner wall of the chamber 1 and the outer periphery of the mounting table 2 and the supporting member 20 to prevent deposition of attachments thereon. A purge gas (shield gas) is flown between the quartz liner 3 and the wall portion of the chamber 1 to prevent the deposition of the attachments on the wall portion and contamination that might be resulted thereby.

The top of the chamber 1 is opened, and a shower head 4 is provided to protrude into the chamber 1 from the top opening. The shower head 4 serves to inject a film forming gas, which is supplied from a gas supply mechanism 7 to be described later, into the camber 1. The shower head 4 includes a gas introduction plate (gas introduction part) 40, a gas diffusion plate (gas diffusion part) 43, and a gas injection plate (gas injection part) 41 arranged in that order from the top.

The gas introduction plate 40 is provided with a first inlet hole 42a through which hafnium tetra tertiary butoxide (HTB), which is a metal source gas, and tetraethoxysilane (TEOS) , which is a silicon source gas, are introduced and a second inlet hole 42b through which O₂ gas serving as an oxidizing agent is introduced. The gas diffusing plate 43 has a first and a second gas diffusion space 44a and 44b which extend substantially horizontally at an upper and a lower side thereof, respectively. The first inlet hole 42a is connected to the first gas diffusion space 44a at the upper side, while the second inlet hole 42b is connected to the second gas diffusion space 44b at the lower side. The gas injection plate 41 includes a center portion 46 provided with a plurality of first gas injection holes 45a connected to the first gas diffusion space 44a and a multiplicity of second gas injection holes 45b connected to the second gas diffusion space 44b; and an annular outer peripheral portion 47 provided at outside of the center portion 46 without having the gas injection holes 45a and 45b, wherein the first and the second gas injection holes 45a and 45b are distributed at substantially regular intervals. The outer peripheral portion 47 covers the side surface of the gas diffusion plate 43. With such configuration, the shower head 4 is of a post-mix type that is capable of injecting the HTB and the TEOS through the first gas injection holes 45a independently of the O₂ gas which is injected through the second gas injection holes 45b.

A covering member 48 provided with the first gas injection holes 45a and the second gas injection holes 45b is detachably provided at a bottom surface of the center portion 46 of the shower head 4, i.e., at a surface facing the top surface of the mounting table 2 by means of bolts (not shown) or the like. The surface of the covering member 48 is alumite-treated, and is made to have a reduced reflectivity in advance. Thus, a great decrease in reflectivity of the surface of the shower head 4 due to attachment of decomposed products or reaction products thereto can be prevented.

The outer peripheral portion 47 constituting the shower head 4 is disposed outside the gas introduction plate 40 and the gas diffusing plate 43, and extends upward from the center portion 46 to come into close contact with the side surface of the gas diffusing plate 43. The upper end portion of the outer peripheral portion 47 is outwardly protruded in a flange shape. The shower head 4 is supported in the chamber 4 by the outer peripheral portion 47 being fixed to a lid 10, which is provided at an opening end portion of the chamber 1, by bolts (not shown) or the like. A heat dissipation surface is formed at an upper side or an upper end of the outer peripheral portion 47 along the substantially entire circumference thereof. Further, an annular heat dissipation member 50 for dissipating heat of the shower head 4 is installed along the substantially entire circumference of the outer peripheral portion 47 to correspond to the heat dissipation surface. The heat dissipation member 50 is made of a material having a high thermal conductivity and has therein an annular coolant path 51 through which a cooling medium such as cooling water is flown. The annular coolant path 51 is connected to a coolant source (not shown) via a coolant supply line 52 for supplying the cooling medium and a coolant exhaust line 53 for exhausting the cooling medium, whereby the cooling medium is circulated through the annular coolant path 51 to cool the heat dissipation member 50, thus improving the heat dissipation efficiency of the shower head 4. Further, a thermocouple 54 is provided in the shower head 4, and disposed in the heat dissipation member 50 is a heater 55 that functions to control the temperature of the heat dissipation member 50 cooled down by the cooling medium, i.e., the temperature of the shower head 4, by heating.

With such configuration, a detection signal of the thermocouple 54 is inputted to a temperature controller 56, and based on this detection signal, the temperature controller 56 outputs control signals to a coolant output unit 57 provided in the coolant source and a heater power output unit 58 connected to the heater 55, and performs a feedback control of the temperature of the shower head 4 by adjusting the temperature of the coolant circulated through the coolant path 51 and the heating temperature of the heater 55.

Disposed between the outer peripheral portion 47 and the heat dissipation member 50 is an annular heat transfer control member for controlling a heat transfer therebetween. The heat dissipation member 50 is installed such that it contacts the heat dissipation surface of the outer peripheral portion 4 along the substantially entire circumference thereof via the heat transfer control member 59. By controlling a contact area between the outer peripheral portion 47 and the heat dissipation member 50 by way of properly setting, e.g., the width of the heat transfer control member 59, it is possible to control the heat dissipation efficiency of the shower head 4, i.e., the temperature of the shower head 4, through the use of the heat dissipation member 50.

The annular coolant path 51, the coolant supply line 52, the coolant exhaust line 53, the thermocouple 54, the temperature controller 56, the coolant source and the coolant output unit 57 constitute a cooling mechanism, and the thermocouple 54, the heater 55, the temperature controller 56 and the heater power output unit 58 constitute a heating mechanism. Furthermore, the heat dissipation member 50, the heat transfer control member 59, the cooling mechanism and the heating mechanism constitute a heat dissipating mechanism.

Further, in the event that the heat dissipation efficiency of the heat dissipation member is insufficient when performing cooling by the annular coolant path 51, it is preferable to provide a thermally conductive semiconductor element 60 in the heat dissipation member 50. In such case, the annular coolant path 51 may also be provided inside the heat dissipation member 50.

A gas exhaust chamber 13 protruding downward is disposed at a bottom wall 12 of the chamber 1. A gas exhaust line 14 is connected to a lateral side of the gas exhaust chamber 13, and a gas exhaust unit 15 is coupled to the gas exhaust line 14. By operating the gas exhaust unit 15, the chamber 1 can be depressurized to a specific vacuum level. That is, the gas exhaust chamber 13, the gas exhaust line 14 and the gas exhaust unit 15 constitute a gas exhausting mechanism for evacuating the chamber 1.

Provided at a sidewall of the chamber 1 are a loading/unloading port 16 through which a wafer W is loaded/unloaded between a wafer transfer chamber (not shown) and the chamber 1; and a gate valve 17 for opening or closing the loading/unloading port 16.

The gas supply mechanism 7 includes an HTB tank 70 storing therein liquid HTB which is a hafnium source material; an N₂ gas supply source 71 for supplying N₂ gas serving as an HTB carrier gas; a TEOS tank 82 storing therein liquid TEOS which is a silicon source material; an N₂ gas supply source 83 for supplying N₂ gas serving as a TEOS carrier gas; and an O₂ gas supply source 72 for supplying O₂ gas serving as an oxidizing agent.

A force-fed gas such as He gas is introduced into the HTB tank 70, and the liquid HTB in the HTB tank 7 is directed into the vaporizing unit 74 via a line 73 and a liquid mass flow controller 81 to be vaporized in the vaporizing unit 74. Then, the vaporized HTB is transferred into the first inlet hole 42a of the shower head 4 through a line 76 by the N₂ gas which introduced from the N₂ gas supply source 71 into the vaporizing unit 72 via a line 75 and mass flow controllers 78. Further, though not shown, heater are provided inside the line 76 and the shower head 4 to heat the vaporized HTB at a temperature where the vaporized HTB is kept from condensing.

The TEOS tank 82 is heated to the extent that the liquid TEOS therein partially evaporates, and the TEOS vapor from the TEOS tank 82 is transferred through a line 87 via a high temperature mass flow controller 86 by the N₂ gas introduced from the N₂ gas supply source 83 into a line 84 via a line 85, and as the line 87 joins the line 76, the TEOS vapor is sent into the first inlet hole 42a. The TEOS has relatively low activity, it does not make a reaction with the HTB when it meets the HTB in the line 76 but it rather suppress a decomposition of the HTB. Further, though not shown, a heater is provided inside the line 87 to heat the vaporized TEOS at a temperature where the vaporized TEOS is kept from liquefying.

The O₂ gas from the O₂ gas supply source 72 is transferred through a line 77 into the second inlet hole 42b of the shower head 4.

Further, two valves 79 are provided on each of the line 75 and 77 for gas transfer with the mass flow controller 78 interposed therebetween. Further, valves 79 are installed on the lines 84 and 85, respectively, and valves 79 are also provided on the lines 76, 77 and 87 in the vicinity of the shower head 4.

Each component of the film forming apparatus 100 is connected to and controlled by a process controller 90. Further, connected to the process controller 90 is a user interface 91 which includes keyboard for an operator to input a command or the like to operate the film forming apparatus 100, a display for visualizing and showing an operational status of the film forming apparatus, and so forth.

Further, also connected to the process controller 90 is a storage unit 92 which stores therein control programs to be used in realizing various processes performed by the film forming apparatus 100 under the control of the process controller 90, control programs, i.e., recipes, to be used in operating each component of the film forming apparatus 100 to carry out a desired process according to processing conditions, and so forth. The recipes are stored in a storage medium inside the storage unit 92. The recipes may be stored in a hard disk or a semiconductor memory or may be stored in a portable storage medium such as a CDROM, a DVD, or the like to be set at a certain position in the storage unit 92. Alternatively, the recipes can be transmitted from another apparatus via, for example, a dedicated line.

When receiving a command from the user interface 91, the process controller 90 retrieves a necessary recipe from the storage unit 92 and executes it, whereby a desired process is performed in the film forming apparatus 100 under the control of the process controller 90.

In the film forming apparatus 100 configured as described above, the chamber 1 is evacuated first such that its internal pressure is kept at about 400 Pa, and the wafer W is heated at a certain temperature by the heater 21. In this state, the HTB from the HTB tank 70 is vaporized in the vaporizing unit 74 and is supplied into the first inlet hole 42a. Concurrently, the vaporized TEOS from the TEOS tank 82 is supplied into the first inlet hole 42a and the O₂ gas from the O₂ gas supply source 72 is supplied into the second inlet hole 42b. Accordingly, the HTB and the TEOS are injected from the first gas injection holes 45a and the O₂ gas is injected from the second gas injection holes 45b, so a film formation is begun. At this time, by being heated by the heaters (not shown) in the line 76 and the shower head 4, the HTB is prevented from condensing, and the TEOS is kept from liquefying by being heated by the heaters (not shown) in the line 87 and the shower head 4.

A reaction between the HTB, TEOS and O₂ is made on the wafer W heated up to a film forming temperature, so that a hafnium silicate (HfSiOₓ) film is formed on the wafer W.

After the hafnium silicate film is formed in a specific thickness, the internal pressure of the chamber 1 is adjusted, and the gate valve 17 is opened and the wafer W is unloaded through the loading/unloading port 16, so that a heat treatment of a single wafer is completed.

The outer peripheral portion 47 which constitutes the shower head 4 does not have voids such as gas injection holes 45a and 45b and is extended toward the atmosphere via the heat dissipation member 50. Therefore, during the film formation, heat of the shower head 4, particularly, heat of the gas injection plate 41 is efficiently dissipated toward the atmosphere outside the chamber 1 from the heat dissipation surface of the outer peripheral portion 47 via the heat dissipation member 50. As a result, a temperature rise of the shower head 4 is suppressed, and the shower head 4 can be maintained at a temperature level less than a HTB self-decomposition temperature. Furthermore, since the heat dissipation member 50 is cooled by the cooling medium that circulates through the annular coolant path 51, the heat dissipation efficiency of the shower head 4 by the heat dissipation member further improves.

When reaction products such as oxides or the like are deposited on the covering member 48 provided at the shower head 4 as a result of consecutively using it for a long time, it is preferable to remove, clean and reattach the covering member 48 or to replace the covering member with a new one. In a film forming apparatus, it is difficult to completely prevent the reaction products from being deposited on the shower head. Especially, when a hafnium-based source material such as HTB or the like is used as a film forming gas as in this embodiment, it is possible to perform cleaning or replacement after separating the covering member 48 detachably provided on the center portion 46's surface facing the mounting table 2, though an available cleaning device is not provided inside the chamber. Thus, the reaction products such as oxides layers or the like deposited on the center portion 46 can be easily removed, so that maintenance of the apparatus can be improved.

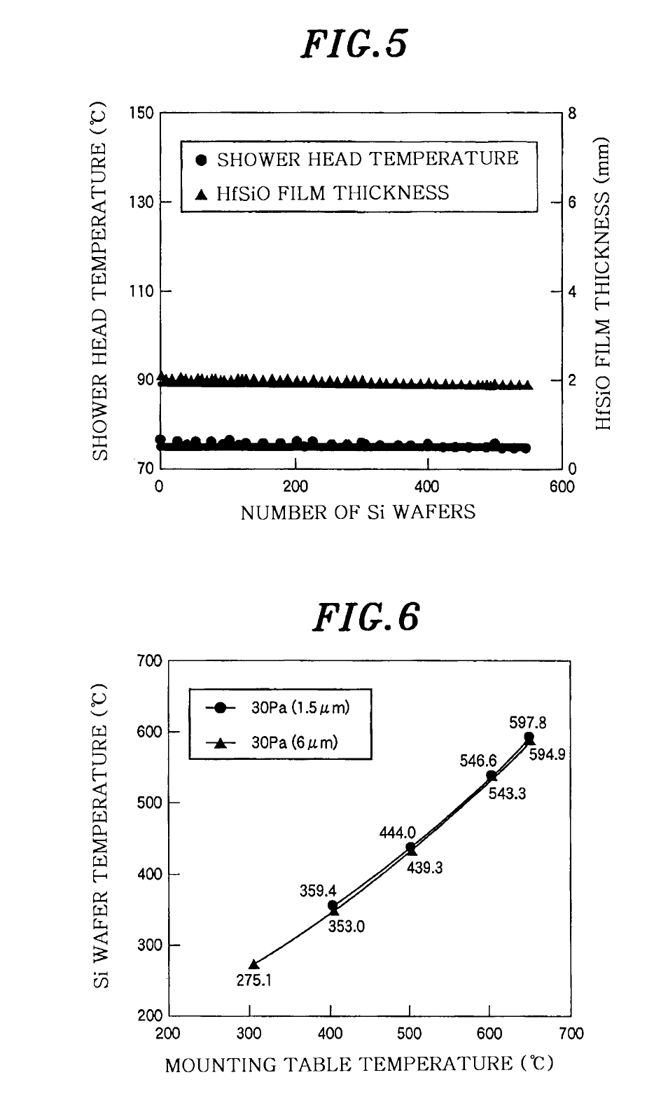

FIG. 5 shows a temperature of the shower head 4 and a film thickness of a hafnium silicate film when successively performing a film formation on a plurality of wafers W by using the film forming apparatus 100. In this experiment, a heating temperature of the mounting table 2 was about 500° C.; a pressure in the chamber 1 was about 30 Pa; and a reference film thickness of the hafnium silicate film was about 2 mm.

As shown in FIG. 5, it was confirmed that even after the film forming process was successively performed on about 600 wafers W, the temperature of the shower head 5 and the film thickness of the hafnium silicate film were stable. This is considered because the heat of the shower head 4 is dissipated by the heat dissipating mechanism or the heat dissipation member 50 and also because the thermal decomposition of the film forming gas 4 is suppressed before it is injected from the shower head 4. Further, it is considered because the deposition of oxide layers or the like on the shower head 4 is suppressed by the covering member 48.

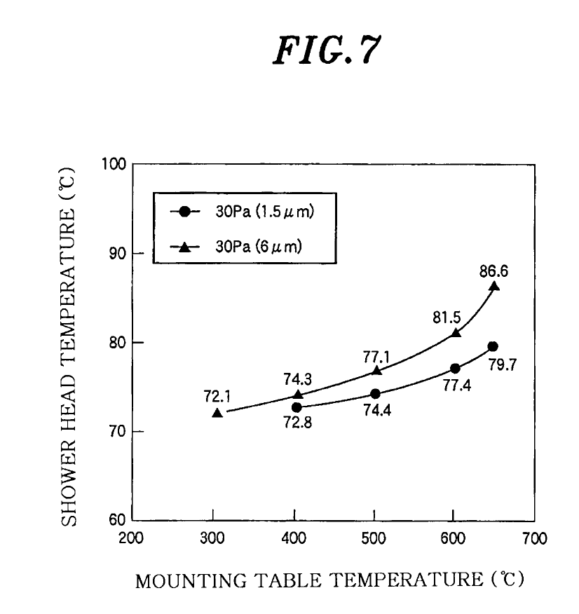

FIG. 6 depicts a relationship between a temperature of the wafer W and a temperature of the mounting table 2 in the case of supplying, into the chamber 1, a film forming gas for forming a film of about 1.5 μm thickness (corresponding to 750 wafers W) and a film forming gas for forming a film of about 6 μm thickness (corresponding to 3000 wafers W) by using the film forming apparatus 100. In this experiment, an internal pressure of the chamber 1 was about 30 Pa, and an actual film formation was not performed on the wafer W. FIG. 7 is a diagram showing a correlation between a temperature of the shower head 4 and a temperature of the mounting table 2 in the same cases as in FIG. 6.

As shown in FIG. 6, it was confirmed that when the film forming gas was supplied to form the film of about 1.5 μm thickness and the film of about 6 μm thickness, the patterns of the temperature increase of the wafer W and the mounting table 2 were substantially same and, also, the temperatures of the wafer W and the mounting table 2 were same. Moreover, as can be seen from FIG. 7, when the film forming gas was supplied to form the film of about 1.5 μm thickness and the film of about 6 μm thickness, the temperature increase of the shower head 4 was suppressed, while the temperature increase patterns of the shower head 4 and the mounting table 2 were substantially same. Namely, if the film forming process is performed on at least 3000 wafers by using the film forming apparatus 100 of the present embodiment, it is possible to suppress the temperature increase of the shower head 4 and prevent the temperature decrease of the wafer W, and also possible to suppress variation in film quality or the like which is caused by a difference in temperature variation between the shower head 4 and the wafer W.

From the above, in the present embodiment, since the wafer W can be exclusively heated to a film forming temperature, it is possible to make a desired reaction take place only on the wafer W by setting the temperature of the shower head 4 to a low level and the temperature of the wafer W to a high level.

The present invention can be variously modified without being limited to the above embodiment. For example, though HTB was used as a film forming material in the above embodiment, the film forming material is not limited thereto but another hafnium alkoxide material, e.g., hafnium tetra-isopropoxide, hafnium tetra-normal butoxide or the like can be employed. Further, although a hafnium silicate film was formed in the present embodiment, the present invention can also be applied to a formation of another metal silicate film. In that case, it is preferable to use an alkoxide material containing the desired metal. For example, the present invention can be applied to a formation of a zirconium silicate film. In that case, zirconium tetra-tertiary butoxide (ZTB) can be used. The present invention can also be applied to a formation of a lanthanum-based metal silicate film. Furthermore, although TEOS was used as a silicon material in the above embodiment, the silicon material can also be a silicon hydride such as disilane, monosilane or the like. In addition, although the present embodiment has been described for the case of processing a semiconductor wafer, the present invention can also be applied to processing other various types of substrates such as a glass substrate for a liquid crystal display or the like.

### INDUSTRIAL APPLICABILITY

In accordance with the present invention, a temperature increase of a shower head is suppressed, so that it is possible to efficiently prevent decrease in the concentration due to decomposition of a source gas or decrease in reflectivity of the shower head due to deposition of decomposed products. Therefore, a decrease in a heating temperature of a wafer can be prevented, thereby improving uniformity or reproducibility of a film formation. As a result, the present invention can be widely applied to a film forming apparatus for performing a desired film forming process by supplying a processing gas from the shower head facing a heated substrate mounted on a mounting table in a processing chamber.

What is claimed is:

1. A processing apparatus comprising:
a processing vessel for accommodating a target substrate to be processed;
a mounting table disposed in the processing vessel, for mounting the target substrate thereon;
a gas injection mechanism disposed to face the mounting table, for injecting a processing gas into the processing vessel;
a gas exhaust mechanism for evacuating the processing vessel; and
a heat dissipating mechanism for dissipating a heat of the gas injection mechanism toward the atmosphere,
wherein the gas injection mechanism includes:
a center portion provided with a number of gas injection holes for injecting the processing gas; an outer peripheral portion provided at outside of the center portion where no gas injection hole is present, and the heat dissipation member dissipates the heat of the gas injection mechanism toward the atmosphere from the substantially entire circumference of the outer peripheral portion.

2. The processing apparatus of claim 1, wherein the heat dissipating mechanism includes a heat dissipation member annularly disposed along the substantially entire circumference of the outer peripheral portion and being in contact with the atmosphere, and the heat dissipation member transfers and dissipates the heat of the gas injection mechanism toward the atmosphere.

3. The processing apparatus of claim 2, wherein the heat dissipation member further includes an annular heat transfer control member for controlling a heat transfer between the outer peripheral portion and the heat dissipation member, and the heat dissipation member is provided to contact the outer peripheral portion along the substantially entire circumference thereof via the heat transfer control member.

4. The processing apparatus of claim 2, wherein the heat dissipating mechanism includes a cooling mechanism provided in the heat dissipation member, for cooling the gas injection mechanism from the outer peripheral portion thereof.

5. The processing apparatus of claim 4, wherein the cooling mechanism includes an annular coolant path through which a cooling medium flows.

6. The processing apparatus of claim 4, wherein the cooling mechanism includes a thermally conductive semiconductor element.

7. The processing apparatus of claim 4, wherein the heat dissipating mechanism further includes a heating mechanism for controlling a temperature of the gas injection mechanism by heating it.

8. The processing apparatus of claim 1, wherein a covering member provided with the gas injection holes is detachably disposed at a surface of the center portion that faces the mounting table.

9. The processing apparatus of claim 8, wherein the surface of the covering member is alumite-treated.

10. The processing apparatus of claim 1, wherein a metal oxide chemical vapor deposition is performed.

11. The processing apparatus of claim 1, wherein the processing gas contains a hafnium-based source material.

12. A processing apparatus comprising:
a processing vessel for accommodating a target substrate to be processed;
a mounting table disposed in the processing vessel, for mounting the target substrate thereon;
a gas injection mechanism disposed to face the mounting table, for injecting a processing gas into the processing vessel;
a gas exhaust mechanism for evacuating the processing vessel; and
a heat dissipating mechanism for dissipating a heat of the gas injection mechanism toward the atmosphere,
wherein the gas injection mechanism includes:
a gas introduction part provided with an gas inlet hole for introducing the processing gas;
a gas injection part provided with a number of gas injection holes for injecting the processing gas toward the mounting table; and
a gas diffusion part disposed between the gas introduction part and the gas injection part, for diffusing the processing gas,
wherein the gas injection part includes:
a center portion provided with the gas injection holes for injecting the processing gas; and
an outer peripheral portion provided at outside of the center portion where no gas injection hole is present,
wherein the heat dissipation member dissipates the heat of the gas injection mechanism toward the atmosphere from the substantially entire circumference of the outer peripheral portion.

13. The processing apparatus of claim 12, wherein the heat dissipating mechanism includes a heat dissipation member annularly disposed along the substantially entire circumference of the outer peripheral portion and being in contact with the atmosphere, and the heat dissipation member transfers and dissipates the heat of the gas injection mechanism toward the atmosphere.

14. The processing apparatus of claim 13, wherein the heat dissipation member further includes an annular heat transfer control member for controlling a heat transfer between the outer peripheral portion and the heat dissipation member, and the heat dissipation member is provided to contact the outer peripheral portion along the substantially entire circumference thereof via the heat transfer control member.

15. The processing apparatus of claim 13, wherein the heat dissipating mechanism includes a cooling mechanism disposed in the heat dissipation member, for cooling the gas injection mechanism from the outer peripheral portion thereof.

16. The processing apparatus of claim 15, wherein the cooling mechanism includes an annular coolant path through which a cooling mechanism flows.

17. The processing apparatus of claim 15, wherein the cooling mechanism includes a thermally conductive semiconductor element.

18. The processing apparatus of claim 15, wherein the heat dissipating mechanism further includes a heating mechanism for controlling a temperature of the gas injection mechanism by heating it.

19. The processing apparatus of claim 12, wherein a covering member provided with the gas injection holes is detachably disposed at a surface of the center portion that faces the mounting table.

20. The processing apparatus of claim 19, wherein the surface of the covering member is alumite-treated.

21. The processing apparatus of claim 12, wherein a metal oxide chemical vapor deposition is performed.

22. The processing apparatus of claim 12, wherein the processing gas contains a hafnium-based source material.

23. A processing apparatus comprising:
a processing vessel for accommodating a target substrate to be processed;
a mounting table disposed in the processing vessel, for mounting the target substrate thereon;
a gas injection mechanism disposed to face the mounting table, for injection a processing gas into the processing vessel; and
a gas exhaust mechanism for evacuating the processing vessel,
wherein the gas injection mechanism includes:
a gas introduction part provided with an gas inlet hole for introducing the processing gas;
a gas injection part provided with a number of gas injection holes for injecting the processing gas toward the mounting table; and
a gas diffusion part disposed between the gas inlet unit and the gas injection part, for diffusing the processing gas,
wherein the gas injection part includes:
a center portion provided with the gas injection holes for injecting the processing gas; and
an outer peripheral portion provided at outside of the center portion where no gas injection hole is present, the outer peripheral portion being annularly formed and having a heat dissipation surface on a top side thereof along the substantially entire circumference thereof,
wherein the processing apparatus further comprises:
a heat dissipation member annularly disposed along the substantially entire circumference of the outer peripheral portion and being in contact with the atmosphere, and the heat dissipation member transfers and dissipates the heat of the gas injection mechanism toward the atmosphere;
a heat transfer control member disposed between the heat dissipation surface and the heat dissipation member to contact the heat dissipation surface and the heat dissipation member along the substantially entire circumference thereof, for controlling a heat transfer from the outer peripheral portion to the heat dissipation member by controlling a contact area between the heat dissipation surface and the heat dissipation member;
a cooling mechanism disposed in the heat dissipation member, for cooling the gas injection mechanism; and
a heating mechanism disposed in the heat dissipation member, for controlling a temperature of the gas injection mechanism by heating the heat dissipation member.

24. The processing apparatus of claim 23, wherein the cooling mechanism includes an annular coolant path through which a cooling mechanism flows.

25. The processing apparatus of claim 23, wherein the cooling mechanism includes a thermally conductive semiconductor element.

26. The processing apparatus of claim 23, wherein a covering member provided with the gas injection holes is detachably disposed at a surface of the center portion that faces the mounting table.

27. The processing apparatus of claim 26, wherein the surface of the covering member is alumite-treated.

28. The processing apparatus of claim 23, wherein a metal oxide chemical vapor deposition is performed.

29. The processing apparatus of claim 23, wherein the processing gas contains a hafnium-based source material.
